(19) United States
(12) Patent Application Publication
(10) Pub. No.: US 2009/0039901 A1
(43) Pub. Date: Feb. 12, 2009

(54) GLAZING COMPRISING A CAPACITIVE RAIN SENSOR

(75) Inventors: Yves Delatte, Jumet (BE); Hugues Leferve, Jumet (BE)

Correspondence Address: AKERMAN SENTERFITT, P.O. BOX 3188, WEST PALM BEACH, FL, 33402-3188, US

(73) Assignee: AGC Flat Glass Europe, Jumet (BE)

(21) Appl. No.: 11/995,120

(22) PCT Filed: Jul. 11, 2006
(86) PCT No.: PCT/EP2006/064090

§ 371 Date: May 21, 2008

(30) Foreign Application Priority Data
Jul. 13, 2005 (BE) 2005/0355

(51) Int. Cl. G01R 27/26

(52) U.S. Cl. 324/664

(57) ABSTRACT

The present invention relates to windows having a capacitive rain detector.

Windows according to the invention are composed of at least one rigid sheet exposed to the rain, the window bearing a capacitive rain detector that is not on the face exposed to rain, the detector comprising electrodes consisting of a thin conducting material, a material that is substantially transparent at these thicknesses, this conducting material covering only a limited part of the window, and substantially corresponding to the electrodes of the detector.

Windows according to the invention are used in particular for motor vehicles.

### CROSS-REFERENCE TO RELATED APPLICATIONS

This application is the entry into the United States of PCT Application Number PCT/EP 2006/064090 filed Jul. 11, 2006 and claims priority from Belgian Patent Application No. 2005/0355 filed Jul. 13, 2005, the entirety of each of which is hereby incorporated by reference.

### BACKGROUND OF THE INVENTION

The present invention relates to windows having a rain detector, and particularly those used on motor vehicles.

The use of sensors is normal for detecting the presence of water on a window, for example to control an operation such as starting the windscreen wipers for motor vehicles. In this application, the sensors marketed are of the type using a change in a light signal on the path on which the water droplets to be detected are situated. The sensor comprises an emitter and a receptor for the light signal consisting for example of a reflected ray.

When sensors operating on these optical signals are used, in particular for motor vehicle windows, they have the disadvantage of leading to the presence of non-transparent elements on the window. Even miniaturized, the sensor covers about ten square centimetres. In order to minimise obstruction on the windscreen, the sensor is usually hidden behind the interior rear-view mirror. Even in this arrangement, the presence of the sensor on the windscreen remains unattractive, at least seen from the outside.

Another type of sensor has been previously proposed that employs a device in which the signal is generated by a variation in capacitance. An assembly of electrodes is positioned on the window. The presence of water on the window, water that has a dielectric constant that is very different from that of air or glass, significantly modifies the capacitance of the system of electrodes. This variation constitutes a signal generated by the sensor.

Previously proposed capacitive sensors have various constructions. Initially, the electrodes of the sensor were directly on the face of the window exposed to the rain. Although this arrangement is very sensitive, it cannot be used in practice since the electrodes are subjected to the abrasive action of the sweeping of the windscreen wipers. The sensor is in fact of necessity positioned in the swept zone, so that the signal is modified as soon as water applied to the window ceases or changes.

Other arrangements have been proposed, in which the electrodes constituting the capacitive sensor are situated on the face of the window that is not exposed to the rain. In these embodiments, the sensors usually have insufficient sensitivity. They moreover have the disadvantage of generating erroneous signals when the window is subject to the formation of mist on the face carrying the sensor.

In order to respond to the limits or the disadvantages indicated above, it has also been envisaged to position electrodes between glass sheets in laminated windows using, in order to constitute these electrodes, a conducting layer coating this window and designed in particular to reduce the transmission of infrared radiation. It is known that layers having this property are conducting layers that are formed of conducting oxides such as ITO (indium tin oxide) or, more frequently of an assembly of layers of which that reflecting infrared is a thin metal layer, usually a silver layer.

The advantage of the layers in question is that they preserve a very high transmission of the visible light spectrum. Typically, laminated windows having these layers offer, as laid down by regulations for motor vehicle windscreens, a light transmission that is not less than 75%.

The formation of the electrodes of sensors made up of these conducting layers is obtained substantially by separating conducting areas from the rest of the layer coating the window, for example by localized ablation of the layer in a design corresponding to the shape of the electrodes.

Capacitive sensors of the latter type, as with those of previous types, have not been exploited industrially up to now. In point of fact, windscreens having layers reflecting infrared radiation remain a product that is not wide-spread commercially by reason of its high cost, a cost connected with difficulties in producing defect-free products.

### SUMMARY OF THE INVENTION

The inventors propose to provide capacitive rain sensors that are compatible with all laminated windows, without, for all this, these windows having a layer limiting the transmission of infrared radiation.

According to the invention, the windows consist of an assembly of sheets, at least one of which is a rigid sheet. The rigid sheet is preferably made of an inorganic glass. It may also consist of a glass termed “organic” that is usual as sheets of polycarbonates frequently used to make the windows of vehicles. Hereinafter, for the sake of simplification, the description is made with reference to glass sheets. The invention applies however to windows having these organic glasses.

In the most usual procedure according to the invention, the sensor is introduced into a laminated window between two rigid sheets joined by means of an interposed sheet made of synthetic material such as polyvinyl butyral (PVB), an ethylene/vinyl acetate resin (EVA), or any conventional interlayer for this type of assembly. The sensor according to the invention may be used in windows called “bilayer” which have a sheet of glass associated with a sheet of a plastic, in particular polyurethane, a material that simultaneously offers plasticity, providing resistance against passengers being thrown out in the event of an accident, and sufficient surface quality to be scratch-resistant. In all cases the electrodes of the capacitive sensor according to the invention are not on the face of the window exposed to the rain, and are not in contact with the atmosphere situated on the other side of the glass. They are at least insulated from this atmosphere by a protective film that is a non-conductor of electricity.

In the remainder of the description, for the purpose of simplification, the invention is presented within the context of laminated windows.

The electrodes of the sensor according to the invention are made of a thin material that is substantially transparent, so that the light transmission in the visible region in the zone covered by these electrodes is not less than 60% and preferably not less than 65%.

The conducting surface may be formed substantially of the surface formed of the electrodes and optionally of conducting elements connecting these electrodes to the device analyzing variations in capacitance. According to the analytical procedure, the sensor may also include earthed electrodes. The electrodes have dimensions and a configuration such that they develop sufficient capacitances to exhibit adequate sensitivity to modifications linked to the presence of water droplets.

The conductors only respond to the need for connecting the electrodes to the analytical device or to earth. They are insensitive as far as possible to measured variations. On account of this, they have a relatively small area compared with those of the electrodes.

The conducting surface may also extend beyond the elements forming the actual sensor. This is the case in particular when the electrodes are formed by ablation of conducting material from a uniformly coated surface, as will be described in detail further on. The presence of these conducting elements adjoining the sensor itself does not strictly speaking participate in measurements. These conducting elements, which may also be earthed, preferably have a limited area so as not to increase unnecessarily the zones of the window having conducting elements which, although substantially transparent, remain discernible on the window.

The surface of the window on which the conducting material extends, is consequently substantially that of the elements of the sensor, and in particular of these electrodes. In practice, the area of electrodes represents at least 10% and preferably at least 50% of the conducting area of the window. It is obvious that these percentages are a function of the extent of the surfaces adjoining the sensor referred to above. These areas may be adjusted at will without, for all that, departing from the scope of the invention. For the reasons indicated, their extension does not however present any practical usefulness, and they are normally limited, their extent depending mainly on the convenience of manufacture of the sensor.

The choice of substantially transparent electrodes meets the need of having a sensor available that does not spoil the general appearance of the window, contrary to sensors that are at present commercially available. In addition, the actual dimensions of the electrodes of the sensor according to the invention are such that only a small part of the area of the window, such as a windscreen, supports the sensor. In practice, for a windscreen, the area concerned is, in order to guarantee good sensitivity, of the order of 0.01 to 0.005 m². In practice, the area covered by the electrodes is advantageously between 0.0004 and 0.04 m². This sufficiently limited area and the transparent nature, means that the presence of the sensor is relatively discrete and in no way interrupts the field of vision, especially as the position of this sensor may be advantageously situated, as for optical sensors, behind the interior rear-view mirror. The only obligation, as for all sensors, is that it be situated in a zone swept by the windscreen wipers.

Limitation of the area of the electrodes makes it possible, above all, to employ such devices, even on windows that do not have conducting layers designed to be an obstacle to the transmission of infrared radiation. Construction is much easier. In point of fact, even in the case where the electrodes of the sensor would be formed of one or more conducting layers of the type of those used to produce these windows with low transmission in the infrared, their production is less restricting by reason of the fact that, on the one hand, since the area is smaller, production is simplified and, on the other hand quality, in particular the total absence of localized defects of the layer which constitutes one of the great difficulties in their production, is not an essential condition for the satisfactory functioning of the sensor. It of course remains preferable for these electrodes to have very uniform layers.

In the production of capacitive sensors according to the invention comprising a conducting layer or assembly of conducting layers, the techniques employed for the formation of an infrared filter are obviously applicable. For layers of the conducting oxide type such as ITO, doped SnO₂ and vanadium oxides, formation is advantageously made by a pyrolysis technique. For assemblies of layers having a conducting metal layer, in particular of silver, formation is preferably obtained by vacuum techniques, such as magnetron sputtering.

In the production of windows having a conducting layer, obtaining good uniformity over all the area leads to deposition being carried out on flat glass sheets, and therefore before the forming operations. These forming operations, substantially of bending and annealing, involve relatively vigorous heat treatments that are by nature liable to affect these layers adversely, in particular metal layers. In the case of an application that only concerns a small area of the window, such as for sensors according to the invention, application may be made before or after forming. In both cases, the operation involves less risks of ending up with defective products. For application before bending, the limited dimensions of the conducting area considerably reduce non-uniformities of the thermal conditions that may effect the surface of the window. It is therefore easy to prevent defects associated with insufficiently precise control over these conditions over the entire surface. For application after bending, the dimensions of the sensor are sufficiently small for the area concerned to appear practically flat. The result is that although some application techniques, in particular vacuum deposition, cannot be used for coating an entire window that has been previously bent, it is not the same for producing the layer used for producing a sensor.

The materials constituting the electrodes all meet conductivity and transparency conditions at the thicknesses used. Conductivity is a significant factor. Measurements in the preferred techniques are carried out by employing relatively high frequencies (several tens of kilohertz). At these frequencies, the materials should be sufficiently conducting so that electric charges and the fields that they generate are sufficiently intense. Silver, aluminium, copper, gold or platinum metal layers may in particular be used. As previously indicated, conducting oxides also constitute a group of materials that may be conveniently used. It is also possible to use conductive lacquers or inks or conducting polymers such as polyethylene dioxythiophene (marketed under the name “Pedot”) or polyanilines (marketed in particular by the Panipol Oy Company).

The application of layers on only part of a window is carried out by conventional means. It consists of techniques such as the pyrolysis of powders or gases, particularly for producing conducting oxide layers. It also consists of deposition techniques termed “vacuum deposition” such as magnetron cathode sputtering, this particularly for deposits of assemblies of layers of which one is a metal layer. It also consists of applying conducting compositions by means of stencils or screen printing. The pattern making up the electrodes may also be printed by projection of the “ink jet” type.

The conducting material reproduces the pattern of the sensor directly or this pattern is obtained from a uniformly coated surface by localized ablation following the desired pattern, or furthermore the conductivity of the material is activated following the pattern in question. Masking, screen printing, stencilling or ink jet printing, decal printing or transfer printing, etc. correspond in particular to the first procedure. Vacuum sputtering techniques or pyrolytic deposition (CVD, LPCVD) usually correspond to the second procedure. Polymer conversion corresponds to the third procedure.

Localized removal of previously applied layers, taking into account the small size of the patterns, in particular the intervals separating the conducting zones from the zones that are not conducting, sometimes of the order of a millimetre or less, may be preferable to masking techniques. In this case, the surface of the sensor is uniformly applied, optionally following a contour corresponding to the periphery of this sensor, and the electrodes are then delimited in relation to each other, as well as the conductor design, by localised ablation of layers previously deposited in the suitable design. The most usual procedure for this very precise type of ablation is the use of a laser beam, but mechanical or chemical ablation may also be envisaged.

In all cases, the ablation characteristics are chosen so that the conducting layer is completely eliminated locally, in this way delimiting zones that are electrically insulated from each other, without going as far as etching the glass substrate.

Although, as indicated above, the sensor may consist of layers deposited on one of the glass sheets of the laminated window, it may also be more convenient to deposit electrodes on a “support” sheet inserted between the glass sheets.

Introduction of a flexible sheet having a layer selectively reflecting infrared is a known alternative to the deposition of layers directly onto the glass sheet. The use in interlayer sheets of a sheet carrying a layer reflecting infrared was nevertheless limited to windows not presenting accentuated curves and especially not having composite curves. Although in point of fact the use of bonding interlayer sheets of the PVB or EVA type lend themselves without too much difficulty to an assembly between two sheets having double curvatures by reason of some elasticity of these materials, the system of layers cannot withstand very accentuated modifications of form without risk of damage. For this reason, the use of such sheets coated with layers reflecting infrared has been limited to certain windows. In motor vehicles, for example, the use of these films generally concerns side windows that are generally bent to a limited extent and above all are substantially of the “cylindrical” type.

The sheets introduced may vary in nature. They consist for example of polypropylene, high- or low-density polyethylene, but especially of polyethylene glycol terephthalate (PET).

In order to prevent layers being stretched during forming, bringing about non-uniform properties over all the surface, the most normal use consists of taking films with relatively low extensibility as a support for these layers. The preferred films consist of polyethylene glycol terephthalate (PET). These films have high mechanical strength, which makes it possible to use them at extremely low thicknesses, of the order of a few tens of microns. These low thicknesses promote a very high transmission of visible light. In other words, the presence of this supplementary film does not bring about a noticeable reduction in the light transmission of the window in which this infrared-reflecting film is introduced on this support.

In a particular manner, the film inserted in the laminated window may be a conductor on its own without it being necessary to apply a supplementary conducting layer thereto. Products of this type are for example products marketed under the name polyolefin premix Preelec TP 9815.

For the application according to the invention, the arrangement consisting of the formation of the electrodes of the sensor on a support that is then introduced between two glass sheets, does not cause the problems previously encountered as regards the introduction of a sheet covering all the window. The sensor and the support thereof are advantageously small in relation to the window supporting this sensor. Even on deep curved windows, and especially with a complex curvature, the introduction of this sensor and the film that supports it do not risk leading to the formation of folds, for example, even if the support introduced has relatively low extensibility.

The ease of formation of the electrodes of the sensor on an added element is certain. The quality of the support does not depend in particular on thermal conditions for the operations previously carried out on the glass sheets of the window. The only constraint is the ability to withstand the conditions that are those for forming the laminate. However, at this stage, the thermal conditions imposed are much less restricting. As an indication, although the glass forming imposes temperatures of the order of 600 to 650° C., assembling a laminated window by means of an interlayer is carried out in an oven at temperatures that normally do exceed 150° C.

Advantageously according to the invention, the conducting circuit making up the sensor is therefore positioned on a support introduced into the laminate. The conducting part is formed on this support under similar conditions to those enabling the sensor to be produced directly on glass sheets, with the advantage that the deposit preferably extends over almost all the support sheet. It is not necessary for the conducting part to be substantially indented from the edges of the support and it may be perfectly co-extensive.

In the production of the conducting circuit, a support sheet may comprise a multiplicity of elements, each constituting a sensor, in order to use to the best advantage the dimensions of the installation for depositing conducting layers. Once the sheet is coated, the sensors are individualized by appropriate cutting. This procedure minimizes the production cost of these elements.

Introduction into the window is advantageously carried out during the lamination operation. The element forming a sensor is inserted for example between a glass sheet and the assembly interlayer sheet, typically of PVB. If, in the event, the element forming the sensor is supported by a material that does not adhere to glass, it is possible to position it between two interlayer sheets. It is also possible to deposit an adhesive on the face of the element in contact with the glass sheet. In a known manner, this adhesive may consist of a PVB powder applied between the glass and the sheets supporting the conducting layers.

The conducting elements making up the electrodes of the sensor should offer a certain capacitance so that modification of the dielectric constant, linked to the presence of water on the window, introduces an appreciable variation in this capacitance. For this reason, the electrodes should provide a certain area taking into account that the thicknesses of the conducting layers are moreover necessarily very small. If the distance between the electrodes is small in order to promote the intensity of electric fields, it is however necessary on one hand for the distance to be sufficient in order to prevent a risk of a short circuit by reason of a possible configuration that is insufficiently precise. It is especially necessary for the area situated between the electrodes to be sufficient, so that the presence of water droplets on the window is detected as soon as these droplets appear, independently of the fact that the distribution of these droplets is of necessity random. In this sense, an increase in the surface that is “sensitive” to the presence of water droplets, increases the probability of finding droplets as soon as they appear.

Although two electrodes are sufficient to produce a signal of the variation in capacitance, the procedure for analyzing this signal may lead to the choice of a different number of electrodes.

With two electrodes, it is advantageous, as described in European application No. 04104149.2, filed on 30 Aug. 2004, to analyze by a technique termed “charge transfer”. According to this technique, the time necessary for transferring a given quantity of electrical charge to the electrodes is measured. This time is a function of the capacitance and therefore of the state of the dielectrics, including the presence of water, in the field of the sensor. A reference serves as a comparison of the time measured in order to determine variations linked to the presence or not of water on the window with which the sensor is associated.

Another technique, previously proposed, for analyzing the variation in the signal, requires a comparison of two capacitances. The technique, termed “differential”, is based on a principle according to which, within the limits for the dimensions of the field on which the droplets are likely to modify the capacitance, two adjacent capacitances are never modified in precisely the same manner, the random distribution not leading to variations that are perfectly of the same amplitude. The analysis therefore consists of detecting an imbalance introduced by the presence of droplets.

In differential procedures, the two capacitances may be formed from three electrodes aligned side-by-side, the central electrode constituting the electrode opposing the other two. This arrangement is illustrated in some of the examples below.

It has been pointed out that the electrodes are very thin in order to take account of the possibility of positioning them between two glass sheets. An excessive thickness would make degassing that accompanies the assembly of the laminate difficult and, at the limit, would not enable the leakproofness of the laminated window to be satisfactorily guaranteed in the zone occupied by the sensor. It is indeed necessary to locate the sensor in the immediate vicinity of the edge of the window. The device for analyzing the signal is advantageously situated as near as possible to the electrodes so as to minimize background noise produced all along the conductors. It is indeed impossible completely to separate off the capacitors corresponding to these conductors themselves. It is nevertheless necessary to minimize this background noise by limiting the distance separating the sensor itself from the means for analyzing the signals, by placing the sensor close to the edge of the window.

The sensor should also be very thin for the reason that it is preferable to have virtually transparent electrodes, and that if their thickness increases too much they of necessity lose this quality. The thickness of the layer is of course a function of the material of which it consists.

For assemblies having a metal layer of the type of those deposited by vacuum sputtering, thicknesses advantageously lie between 25 and 200 Å and preferably between 50 and 150 Å.

In order to obtain high conductivity with the smallest possible thickness, the electrodes advantageously consist of a layer of silver, 60 to 140 Å thick deposited between oxide layers protecting the silver and making it possible to achieve good colour neutrality, particularly in reflection.

For layers based on a conducting oxide, in particular ITO or doped SnO₂, the thickness is substantially greater, of the order of 50 to 100 nm, and more frequently from 100 to 500 nm.

For layers deposited by printing techniques, thicknesses may be even greater. They are situated for example between 1 and 50 μm and preferably between 5 and 20 μm.

### BRIEF DESCRIPTION OF THE FIGURES

The invention is described in a detailed manner hereinafter with reference to the figures wherein:

FIG. 1 is a schematic representation in perspective of the principle of employing a rain detector on a motor vehicle windscreen;

FIG. 2 is a section along A-A of FIG. 1;

FIG. 3 is an enlarged view of part of FIG. 2;

FIG. 4 is a similar view to FIG. 3 for an embodiment according to the invention;

FIGS. 5a and 5b show, in section, two other embodiments according to the invention, similar to that of FIG. 4;

FIG. 6 is an exploded illustration of the assembly of elements of the type shown in FIG. 5a;

FIGS. 7a and 7b show schematically an embodiment of the sensor;

FIG. 8 shows schematically a drawing of the electrodes of a sensor according to the invention;

FIG. 9 is another drawing of electrodes of a sensor according to the invention; and

FIG. 10 is again an embodiment of a sensor according to the invention.

### DETAILED DESCRIPTION

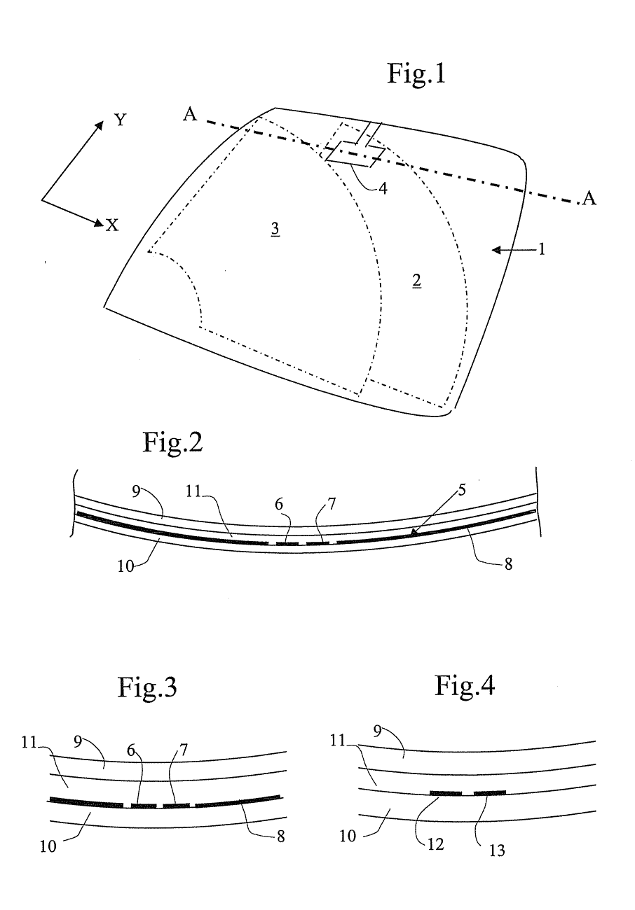

FIG. 1 shows a typical arrangement of a rain sensor on a motor vehicle windscreen (1). The windscreen has composite curves in the width direction (x direction) and in the height (Y direction), the usual form in current models.

The rain sensor (4) is of necessity situated on the windscreen in a zone (2, 3) swept by the windscreen wipers. In the figure these zones are shown schematically by broken lines. This arrangement is controlled by the fact that the sensor (4) is designed to trigger the movement of the windscreen wipers in the presence of water on the swept zones. Away from these zones, water may remain after rain has no longer fallen. Consequently, if the sensor was positioned outside these swept zones, the movement of the windscreen wipers could be unnecessarily maintained.

The sensor (4) in optical detection systems that include non-transparent elements is preferably positioned at a point where it causes no obstruction for the driver. If however, it is still in the field of vision, this location is preferably already obscured by another functional element. Normally, optical sensors are positioned behind the interior rear-view mirror.

In the case of capacitive sensors according to the invention, the fact that the electrodes are very largely transparent to visible radiation, offers greater latitude in the choice of this location, even if the area occupied by the sensor is substantially greater than that masked by conventional optical sensors.

Capacitive sensors operate with an assembly for analyzing the signals that they generate. Most commonly, the assembly in question consists of an electronic circuit that takes up little room. This may even be reduced to a “chip” of a few square millimetres or less. This assembly is usually non-transparent. For this reason, it is advantageous to locate it away from the transparent part of the window. For the reasons indicated, the analytical assembly is however as near as possible to the electrodes of the sensor. It is located for example behind the enamelled strips that are very often positioned in the borders of windows. Taking into account their overall size, which is very often considerably reduced, they may even be inserted between the glass sheets, on the interlayer of laminated windows.

The conductors connecting the electrodes to this analytical circuit are inevitably the source of interfering signals, unless they are protected by “screening”. This protection is not generally desirable in as much as it is established by means of sheaths that are not transparent. In order to proceed so that the conductors can be seen as little as possible, they are preferably unsheathed. They develop a certain capacitance themselves that is superimposed on that of the electrodes of the sensor. In order to minimize this interference effect, it is desirable to shorten these conductors as much as possible. For this reason, the sensor is normally close to the edge of the window.

In the form shown in FIG. 1, the sensor is, as is frequently the case, in a central high position, that is to say behind the rear-view mirror. Taking into account the substantially transparent character, another location is nevertheless possible.

In former proposals for transparent capacitive sensors, these were systematically provided in a conducting layer of which the main function was to form an obstacle, at least partly, to the transmission of infrared. Such a layer obviously extends over virtually all the area of the window with the abovementioned disadvantages.

The section of FIG. 2 shows the arrangement that could have been adopted in the case of this type of embodiment if that had been developed commercially, which is not the case up to now.

The section of the window, of which the curvature has been deliberately exaggerated, comprises two glass sheets (9, 10). These sheets are assembled in a conventional manner by means of an interlayer sheet (11), for example of the PVB type.

The main feature of the implementation of these sensors is therefore the existence of a layer (5) that extends over practically all the area of the window, with the exception of a few parts that, during manufacture, have been the subject of localized resists or ablation. In the case of sensors formed in this layer (5) the electrodes (6, 7) are drawn by delimiting corresponding zones in the layer so as to insulate them from the remainder (8) of the surface of this layer. Where appropriate, the remainder of the layer participates in forming the electrical circuit of the sensor, in particular by forming an earth that may be in contact with the rest of the vehicle.

On FIG. 2, the electrodes are shown without respect to the actual scale, for ease of comprehension. In particular, the dimensions of the electrodes and the distances between these are deliberately increased. In practice, the distances between the electrodes are relatively small, less than one millimetre, in order to maximize the electrical field. As previously indicated however, a compromise has to be established between a sufficiently intense field and a sufficient area to cover a variation in field that is entirely representative of the phenomenon detected.

FIG. 3 shows a detail of FIG. 2 corresponding to the location of the electrodes. The curvature of the window is, as previously, very accentuated in relation to actual forms encountered, in order to emphasize more satisfactorily the types of difficulty that may arise when a layer is put in place covering all the area of the sheet. As against this, the diagram of FIG. 4 illustrates an embodiment of the invention in which the electrodes (12, 13) are formed independently of a layer covering the surface.

In the embodiment illustrated in FIG. 4, the electrodes are for example formed by depositing a conducting layer limited to the extent of these electrodes. This operation may be carried out on the previously formed sheet so as to prevent any risk of damage. The fact that the sheet is not flat at this stage of the process does not occasion any particular difficulty of application in as much as the area concerned has limited dimensions so that variation in deposition conditions are practically not discernible.

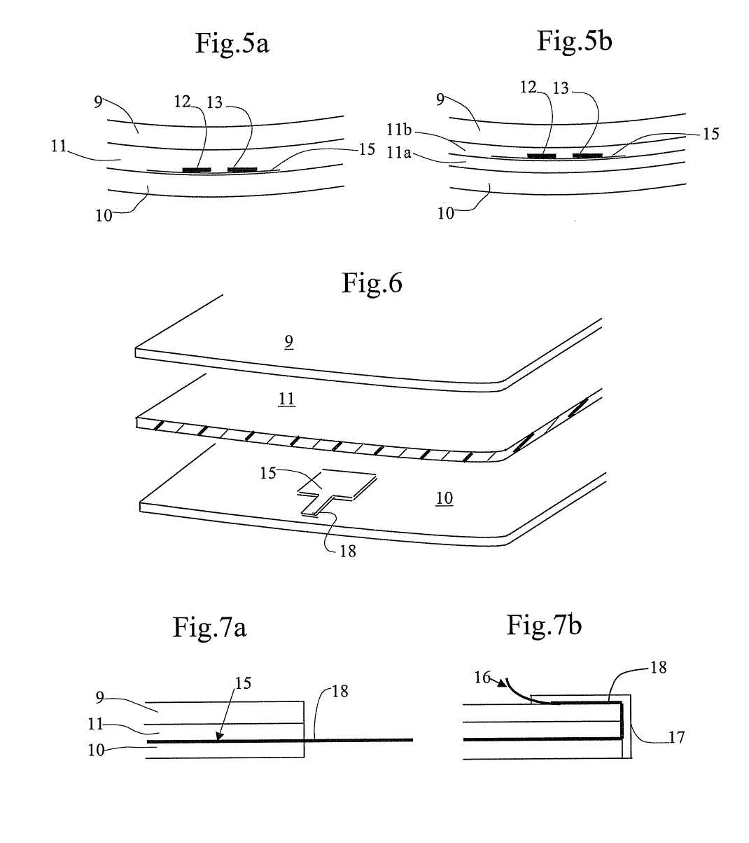

FIGS. 5a, 5b and 6 show particularly advantageous embodiments. In these embodiments, the electrodes are formed on a non-conducting transparent film (15) made of a material compatible with the components with which it is in contact, substantially the glass sheet (10) and the assembling insert (11). A well-known material for this type of application is polyethylene glycol terephthalate (PET) that has the advantage of being extremely strong even at very small thicknesses. This material also has the peculiarity of not lending itself easily to stretching. For this reason it is not generally used in windows having curvatures of the spherical type, when the aim is to form an infrared filter. In the present case, since the area of the electrodes remains of limited dimensions, the curvatures are practically without any influence over the insertion of this support film (15).

The use of this element supporting the electrodes offers several advantages. It avoids having to form a conducting layer over a large area which, apart from the presence of the sensor, does not carry such a layer, an operation that presents difficulties by reason of the dimensions of the handled glass sheets, an operation that is all the more inconvenient if it is carried out on previously bent sheets. The insertion of the support (15) takes place at the stage where the laminate is assembled, while subsequent treatments do not involve exposure to very high temperatures. The assembly under conventional conditions is carried out in an oven at a temperature of the order of 150° C.

The PET film does not adhere to the glass on its own. If necessary, a PVB powder or any other known suitable adhesive may be deposited on the face in contact with the glass in the forms shown in FIGS. 5a and 6. However, the small dimensions of the support (15) and the fact that it may be completely surrounded with zones on which the interlayer is well adhered to two glass sheets, means that the presence of these adhesives is not systematically necessary. Where appropriate, the use of the adhesive may be limited to the zone where conductors leave the laminate on the edge of the window so as to guarantee if necessary perfect leakproofness of this assembly.

In the procedure shown in FIG. 5b, the support (15) for the sensor is positioned between two interlayer sheets (11a) and (11b). This procedure leads to an assembly having all the strength characteristics that are those of conventional laminated windows, in as much as adhesion to the glass sheets is made directly with the interlayers.

Deposition of conducting layers is advantageously carried out on a support film (15) with dimensions that are much greater than those of the sensor alone, in order best to utilise the deposition installations. A multiplicity of sensors may be positioned simultaneously. The sensors are then individualized by cutting the film coated in this way.

The presence of the support film (15) is advantageously used in order to form, at the same time, conductors associated with the electrodes. The support overlaps the perimeter of the actual electrodes in order to include a tab on which these conductors are established. The conductors advantageously consist of the same layer or assembly of layers forming the electrodes. The tab (18) advantageously extends so as to overlap the edge of the glass (9, 11) in order to facilitate the connection of the means for analyzing the signals.

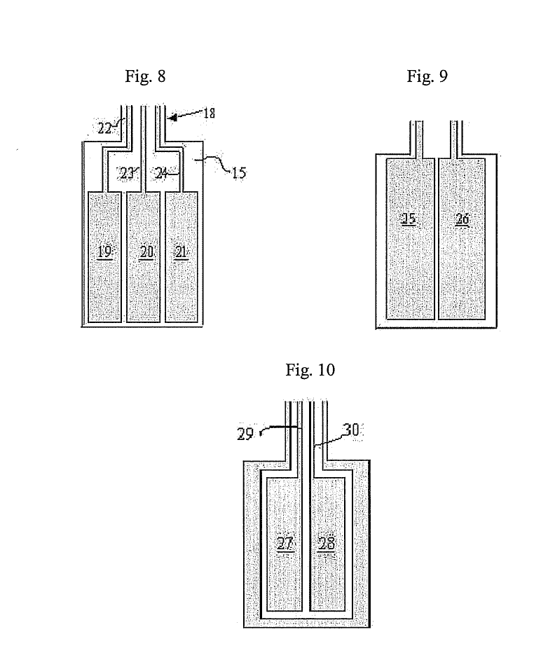

FIGS. 7a and 7b illustrate procedures for connecting the electrodes. The support film (15) held between the glass sheet (10) and the interlayer sheet (11) overlaps the edge of the window in a part (18) forming, as required, a tab that is narrower than the part supporting the electrodes. This part (18) is advantageously folded back as in 7b onto the face of the window and adhered to this face by local encapsulation (17) by means for example of a thermoplastic material formed directly on the edge of the window. The connections with the conductors linked to the analytical device are provided for example by means of strip conductors (16) applied to the ends of the part (18). Fixing the conductors by means of encapsulation (17) makes it possible where appropriate to avoid the necessity of soldering.

FIGS. 8 and 9 illustrate, in a non-limiting manner, electrode designs that may be used according to the invention. In these figures, the electrodes are shown on a support (15) of the type previously described.

The sensor of FIG. 8 has three electrodes (19, 20, 21). It is advantageously used in a measurement of the “differential” type. According to this differential procedure, two capacitances are used, one serving to measure and the other for reference. An imbalance between the two capacitances constitutes the signal that is the subject of the analysis. In the procedure presented, the central electrode is common to the two capacitances made up respectively of the electrodes (19, 20) on the one hand and (20, 21) on the other. The identity of the electrodes (19) and (21) and the spaces between the electrodes lead to identical capacitances. This arrangement is not necessary for implementation. When the capacitances constituted are different, it is the ratio of the signal coming from these capacitances that is followed. Any modification in the conditions of the electrical fields also modifies the ratio of these signals. It is this modification that constitutes the measurement of the appearance of water droplets.

The “differential” form shown in FIG. 8 may be achieved with more than three electrodes. It is possible in particular to produce an assembly of four electrodes associated pairwise.

The differential procedure is only one route for analyzing variations of capacitive sensors. FIG. 9 illustrates a type of sensor that has only two electrodes (25, 26). This type of sensor is put into use by means of a charge transfer measurement. In this procedure it is the instantaneous changes in charge transfer time that are measured in a permanent manner. This analysis consequently makes it possible to eliminate factors such as temperature that introduce spurious capacitance variations in the desired measurement.

In the two designs for sensors, the electrodes are positioned side by side and not interlaced in order to prevent, as much as possible, interferences of fields that disturb signals by background noise. In order to maintain a sufficient sensitive area, an area corresponding to the space between the electrodes, the latter should of necessity extend over a sufficient length. In practice, several centimetres are sufficient to have a suitable signal. In order to limit the area of the sensor on the window, an attempt is made to keep dimensions as small as the sensitivity of the sensor will permit.

In FIGS. 8 and 9 the conducting material is limited to the electrodes and to the feeds therefor, all placed for example on a support of which the limits correspond to the external contour. The arrangement of FIG. 10 differs in that the conducting material shown in grey covers all the support. The non-conducting parts, in white, are obtained for example by abrading the conducting layer following the design of the electrodes (27, 28) and that of the supply conductors (29, 30).

The designs for electrodes presented above as an example are obviously not limiting. Similarly, these designs can be used whether the electrodes are on a support film or whether the same electrodes are formed directly on a glass sheet.

1. Window composed of at least one rigid sheet exposed to the rain, the window bearing a capacitive rain detector that is not on the face exposed to rain, the detector comprising electrodes consisting of a thin conducting material, a material that is substantially transparent at these thicknesses, this conducting material covering only a limited part of the window, and substantially corresponding to the electrodes of the detector.

2. Window according to claim 1, in which the electrodes of the detector represent at least 10% and preferably at least 50% of the area occupied by the conducting material on this window.

3. Window according to claim 1, in which the electrodes have a light transmission in the visible that is not less than 60% and preferably not less than 65%.

4. Window according to claim 1, in which the area of the electrodes is between 0.0004 and 0.04 m².

5. Window according to claim 1, in which the electrodes consist of an assembly of thin layers comprising a metal layer, an assembly formed by vacuum deposition.

6. Window according to claim 1 in which the electrodes consist of at least one layer of a conducting oxide.

7. Window according to claim 1 in which the electrodes are made by a printing method on one of the constituents of the window.

8. Window according to claim 1 in which the electrodes are made of a conducting polymer.

9. Window according to claim 1, in which conducting material of which the electrodes are made also constitutes the conductors associated with these electrodes.

10. Window according to claim 1, consisting of a laminated assembly, the detector being positioned between the two sheets of this window.

11. Window according to claim 1, consisting of a sheet of annealed glass, the detector being coated with a non-conducting insulating transparent film.

12. Laminated window comprising two glass sheets joined by a thermoplastic interlayer sheet, and including a capacitive rain detector, in which the electrodes are supported by a thin film, the film being introduced between the glass sheets.

13. Window according to claim 12, in which the dimensions of the film supporting the electrodes are substantially those of the sensor, namely those of the electrodes and as the case may be the connections.

14. Window according to claim 12, in which the film supporting the electrodes is a PET film.

15. Window according to claim 12, in which the film supporting the electrodes is positioned between two interlayer sheets for assembling the laminate.

16. Window according to claim 12, in which the film supporting the electrodes is positioned between a glass sheet and the interlayer sheet for assembling the laminate.

17. Window according to claim 16, in which the film supporting the electrodes in contact with the glass sheet is fixed to this sheet by means of an adhesive.

18. Window according to claim 17, in which the adhesive is introduced with the support film of which it covers the face brought into contact with the glass.

19. Window according to claim 12 in which the film supporting the electrodes and conductors is uniformly coated and cut out in the design of the sensor, its application to the glass being carried out from a flexible support by a transfer operation.
